(19) United States
(12) Patent Application Publication
(10) Pub. No.: US 2025/0372982 A1
(43) Pub. Date: Dec. 4, 2025

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Hirokuni Kurashiki, Susono-shi (JP)

(21) Appl. No.: 19/220,101

(22) Filed: May 28, 2025

(30) Foreign Application Priority Data
Jun. 4, 2024 (JP) 2024-090413

(51) Int. Cl. H02G 3/08; B60R 16/023; H01R 25/16; H05K 7/20

(52) U.S. Cl. CPC H02G 3/081; B60R 16/0239; H01R 25/161; H05K 7/20509; H01R 2201/26

(57) ABSTRACT

An electrical connection unit includes a circuit constitution body, a heat dissipation plate, and a heat transfer member. The circuit constitution body includes resistors and a board facing the resistors. The heat dissipation plate is provided to overlap the circuit constitution body in a thickness direction of the board, and is made of a material having a thermal conductivity higher than that of the board. The heat transfer member is provided between the circuit constitution body and the heat dissipation plate, and thermally connects the circuit constitution body to the heat dissipation plate. One or more weight reduction portions formed to be thinner than other portions of the heat dissipation plate or penetrate the heat dissipation plate are formed in the heat dissipation plate at positions overlapping the board and not overlapping at least part of the heat transfer member when viewed from the thickness direction.

### BACKGROUND OF THE INVENTION

### Field of the Invention

Embodiments of the present invention relate to an electrical connection unit.

Priority is claimed on Japanese Patent Application No. 2024-090413 filed in Japan on Jun. 4, 2024, the content of which is incorporated herein by reference.

### Description of the Related Art

There is an electrical connection unit including a plurality of electronic components.

### PRIOR ART DOCUMENT

### Patent Document

Patent Document 1: Japanese Unexamined Patent Application, First Publication No. 2024-037492

### SUMMARY OF THE INVENTION

Incidentally, an electrical connection unit is expected to be reduced in weight.

An embodiment provides an electrical connection unit that can be reduced in weight.

An electrical connection unit according to an embodiment includes a circuit constitution body, a heat dissipation plate, and one or more heat transfer members. The circuit constitution body includes a plurality of resistors and a board facing the plurality of resistors. The heat dissipation plate is provided to overlap the circuit constitution body in a thickness direction of the board, and is made of a material having a thermal conductivity higher than that of the board. The heat transfer member is provided between the circuit constitution body and the heat dissipation plate, and thermally connects the circuit constitution body to the heat dissipation plate. One or more weight reduction portions that are formed to be thinner than other portions of the heat dissipation plate or penetrate the heat dissipation plate in the thickness direction are formed in the heat dissipation plate at positions overlapping the board and not overlapping at least a part of the heat transfer member when viewed from the thickness direction.

According to an embodiment, an electrical connection unit that can be reduced in weight can be provided.

### BRIEF DESCRIPTION OF THE DRAWINGS

FIG. 1 is a cross-sectional view illustrating an electrical connection unit according to an embodiment.

FIG. 2 is a perspective view for describing a main body of the embodiment.

FIG. 3 is a perspective view for describing a subunit of the embodiment.

FIG. 4 is a partially exploded perspective view of the subunit of the embodiment.

FIG. 5 is a perspective view for describing an electronic component and a connection component according to the embodiment.

FIG. 6 is a perspective view for describing the electronic component and the connection component according to the embodiment.

FIG. 7 is a perspective view illustrating a routing board of the embodiment.

FIG. 8 is a partially exploded perspective view of the routing board according to the embodiment.

FIG. 9 is a cross-sectional view taken along line F9-F9 in FIG. 4.

FIG. 10 is a plan view illustrating the routing board according to the embodiment.

FIG. 11 is a partially exploded perspective view of the electrical connection unit according to the embodiment.

FIG. 12 is a bottom view illustrating the routing board of the embodiment.

FIG. 13 is a cross-sectional view taken along line F13-F13 of a structure illustrated in FIG. 10.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. Note that the specific constitution described below does not limit an applicable scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. “Accommodation” is not limited to a case where the entire component is accommodated, and may include a case where only part of the component is accommodated. The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

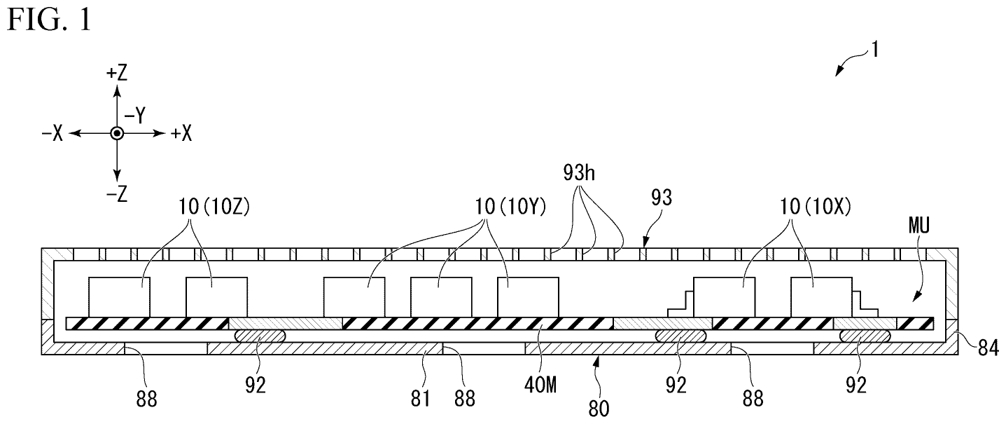

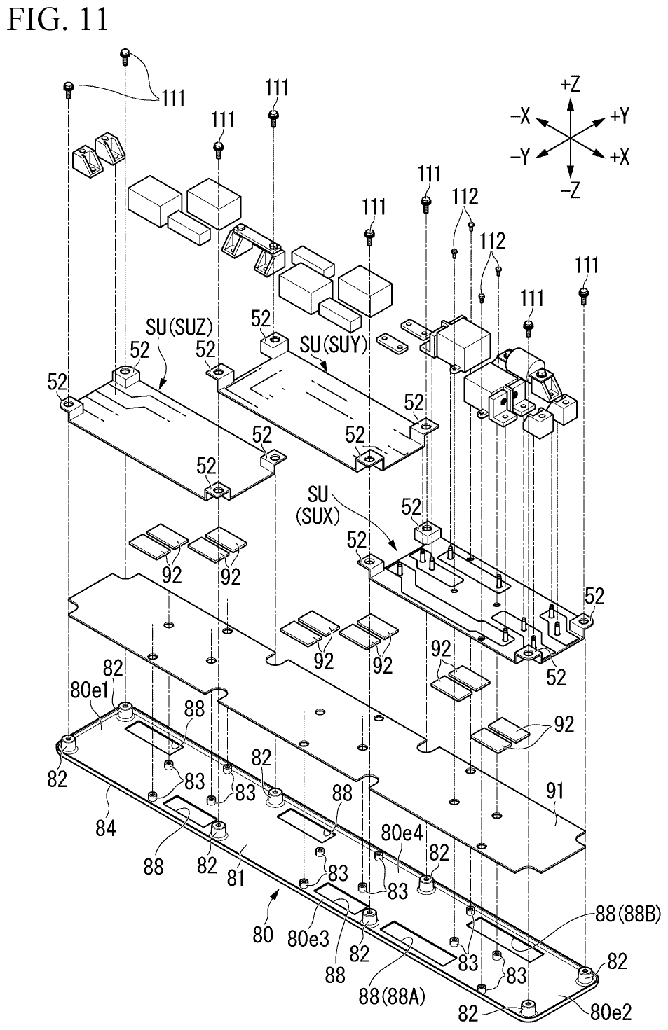

In the present disclosure, a +X direction, a −X direction, a +Y direction, a −Y direction, a +Z direction, and a −Z direction are defined as follows. The +X direction is a direction from a first end 80e1 to a second end 80e2 of a metal plate 80 that will be described later (see FIG. 11). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 80e3 to a fourth end 80e4 of the metal plate 80 that will be described later (see FIG. 11). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 80 that will be described later toward a main body MU (see FIG. 1). The −Z direction is a direction opposite to the +Z direction. Hereinafter, in a case where the +Z direction and the −Z direction are not distinguished, the directions will be simply referred to as “Z direction”. The Z direction is an example of a “thickness direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### 1. Constitution of Electrical Connection Unit 1

FIG. 1 is a cross-sectional view illustrating an electrical connection unit 1 of an embodiment.

The electrical connection unit 1 illustrated in FIG. 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

The electrical connection unit 1 includes, for example, a main body MU, a metal plate 80, an insulating sheet 91 (see FIG. 11), a plurality of heat transfer members 92, and an insulating cover 93.

### 2. Main Body MU

First, the main body MU will be described.

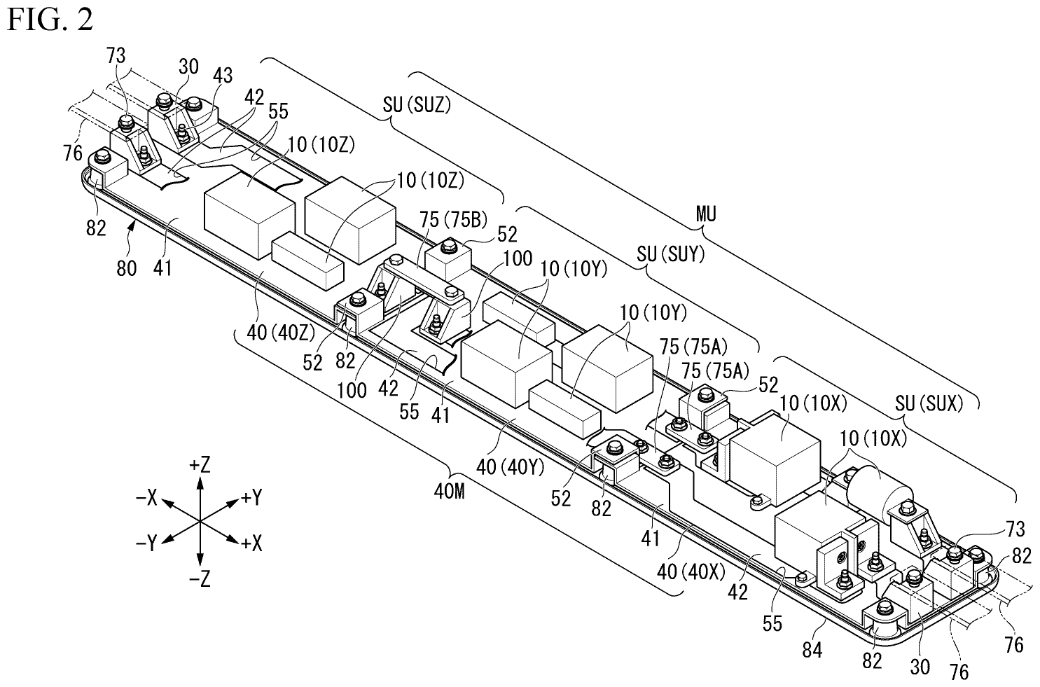

FIG. 2 is a perspective view for describing the main body MU.

The main body MU illustrated in FIG. 2 is a portion that performs a main function (for example, switching of electrical connection states or overcurrent protection) of the electrical connection unit 1. The main body MU is divided into, for example, a plurality of subunits SU. The main body MU is formed by, for example, connecting a plurality of subunits SU. In the present embodiment, the main body MU includes three subunits SU (first to third subunits SUX, SUY, and SUZ). Each subunit SU may be referred to as a “circuit constitution body”.

The first subunit SUX has a first electrical function. The first subunit SUX includes, for example, a plurality of electronic components 10X and a first routing board 40X. The plurality of electronic components 10X are electrically connected to the first routing board 40X.

The second subunit SUY has a second electrical function. The second function is a function different from the first function. The second subunit SUY includes, for example, a plurality of electronic components 10Y and a second routing board 40Y. The plurality of electronic components 10Y are electrically connected to the second routing board 40Y.

The third subunit SUZ has a third electrical function. The third function is a function different from the first function and the second function. The third subunit SUZ includes, for example, a plurality of electronic components 10Z and a third routing board 40Z. The plurality of electronic components 10Z are electrically connected to the third routing board 40Z.

In the present embodiment, the three subunits SUX, SUY, and SUZ are disposed to be arranged in the X direction. For example, the first subunit SUX is disposed on the +X direction side with respect to the second subunit SUY. The first subunit SUX and the second subunit SUY are electrically connected via a coupling bus bar 75 extending between the first routing board 40X and the second routing board 40Y. On the other hand, the third subunit SUZ is disposed on the −X direction side with respect to the second subunit SUY. The third subunit SUZ and the second subunit SUY are electrically connected via the coupling bus bar 75 extending between the third routing board 40Z and the second routing board 40Y. The coupling bus bar 75 is disposed on the side opposite to the metal plate 80 with respect to the plurality of subunits SU.

In the present embodiment, the three routing boards 40X, 40Y, and 40Z included in the three subunits SUX, SUY, and SUZ are disposed on the same plane. In other words, the three routing boards 40X, 40Y, and 40Z are disposed at the same height position in the Z direction. One large routing board 40M is formed by the three routing boards 40X, 40Y, and 40Z.

In the present embodiment, the three subunits SUX, SUY, and SUZ have the same or similar basic structure. Therefore, one subunit SU will be described in detail below as a representative. Hereinafter, in a case where the first subunit SUX, the second subunit SUY, and the third subunit SUZ are not distinguished, the subunits will be simply referred to as “subunit SU”. In a case where the electronic component 10X, the electronic component 10Y, and the electronic component 10Z are not distinguished, the electronic components will be simply referred to as “electronic component 10”. When the first routing board 40X, the second routing board 40Y, and the third routing board 40Z are not distinguished, the routing boards will be simply referred to as “routing board 40”. The routing boards 40, 40X, 40Y, 40Z, and 40M are examples of “boards”.

### 3. Constitution of Subunit SU

Next, a constitution of the subunit SU will be described.

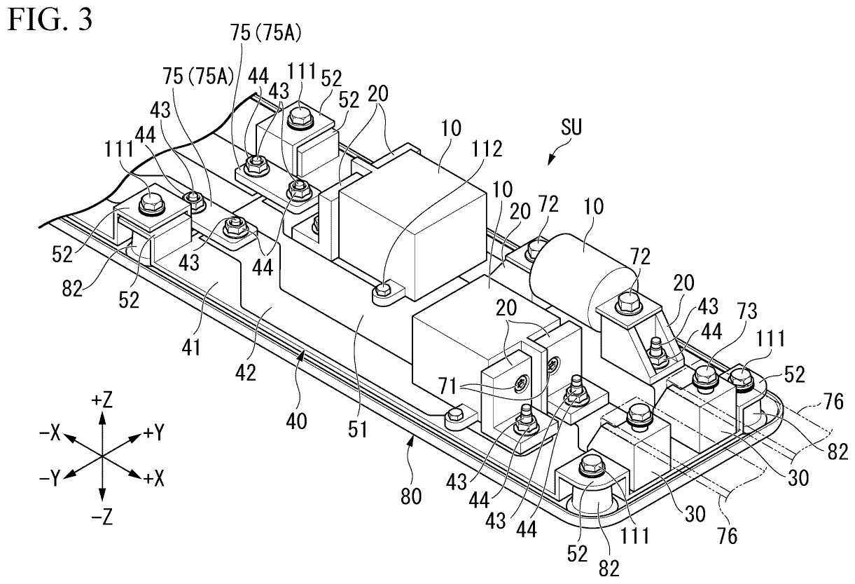

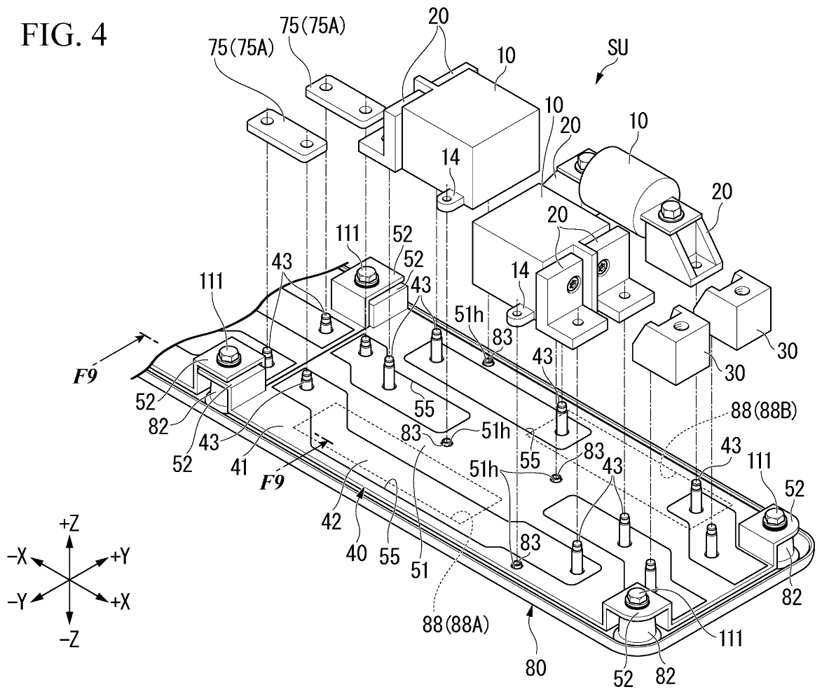

FIG. 3 is a perspective view for describing the subunit SU. FIG. 4 is a partially exploded perspective view of the subunit SU.

As illustrated in FIGS. 3 and 4, the subunit SU includes, for example, a plurality of electronic components 10, a plurality of connection components 20 for component connection, a plurality of connection components 30 for external connection, a routing board 40, a plurality of fastening members 71, 72, and 73, and a connection component 100 for unit connection (see FIG. 2).

### <3.1 Electronic Component 10 and Connection Component 20 for Component Connection>

First, the electronic component 10 and the connection component 20 will be described.

The electronic component 10 is an electronic component mounted according to a function required for the subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. Note that the type of the electronic component 10 is not limited to the above example. The electronic component 10 is, for example, a heat generating component that generates heat at the time of energization. Hereinafter, a first-type electronic component 10M and a second-type electronic component 10N will be described as examples of the electronic component 10. The electronic component 10 is an example of a “resistor”.

The connection component 20 is a component that electrically connects the electronic component 10 to the routing board 40. The connection component 20 forms part of an energization path in the subunit SU. The connection component 20 is made of a metal (for example, copper or a copper alloy). Hereinafter, a first-type connection component 20M and a second-type connection component 20N will be described as examples of the connection component 20. The connection component 20 is an example of a “resistor”.

### <3.1.1 First-Type Electronic Component 10M>

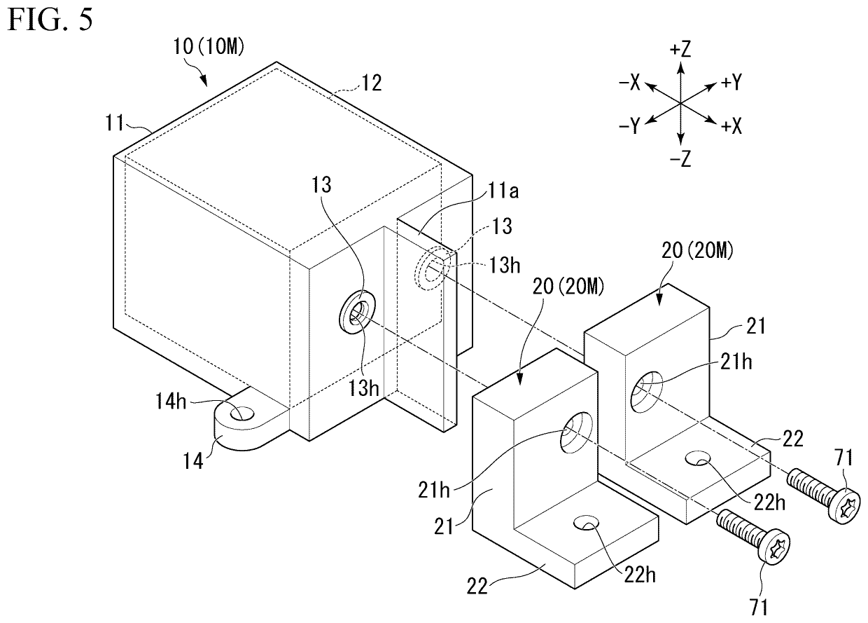

FIG. 5 is a perspective view illustrating the first-type electronic component 10M and the first-type connection component 20M.

As illustrated in FIG. 5, the first-type electronic component 10M is an electronic component 10 in which a plurality of terminals 13 are disposed to be arranged at one end of the electronic component 10M. The electronic component 10M includes, for example, a case 11, a component body 12, a plurality of terminals 13, and a plurality of attachment portions 14.

### (Case 11)

The case 11 is an outer member that forms most of the outer shape of the electronic component 10M. The case 11 is made of, for example, synthetic resin and has an insulating property. The case 11 accommodates the component body 12. The case 11 and the component body 12 may be integrally formed.

In the present embodiment, the case 11 has an insulating rib 11a that protrudes in the horizontal direction (for example, the X direction) and extends in the Z direction. The insulating rib 11a has, for example, a plate shape formed in the horizontal direction (for example, the X direction) and the Z direction. The insulating rib 11a extends over the entire length of the case 11 in the Z direction, for example. The insulating rib 11a is disposed between the plurality of terminals 13. The insulating rib 11a electrically insulates the adjacent terminals 13 from each other. In the present embodiment, part of the insulating rib 11a is disposed between two connection components 20M connected to the electronic component 10M. The insulating rib 11a electrically insulates the two connection components 20M connected to the electronic component 10M from each other.

### (Component Body 12)

The component body 12 is a portion that performs a main function of the electronic component 10M. For example, in a case where the electronic component 10M is a relay, the component body 12 includes a switch (for example, a contact) that switches between a conductive state and a non-conductive state. For example, in a case where the electronic component 10M is a fuse, the component body 12 includes a fusion portion that is fused when an overcurrent flows. For example, in a case where the electronic component 10M is a capacitor, the component body 12 includes a portion that stores electric charge.

### (Terminal 13)

The terminal 13 is an electrical connection portion exposed to the outside of the case 11. The terminal 13 is electrically connected to the component body 12 inside the case 11. In the present embodiment, a plurality of terminals 13 are provided. One of the plurality of terminals 13 is a positive electrode side terminal 13. The other terminal of the plurality of terminals 13 is the negative electrode side terminal 13.

The plurality of terminals 13 are provided at one end of the electronic component 10M in the horizontal direction (for example, the X direction). The terminals 13 are disposed to be arranged in the horizontal direction (for example, the Y direction). Each terminal 13 has an attachment hole 13h to which a fastening member 71 (for example, a screw or a bolt) is attached. The attachment hole 13h is open in the horizontal direction (for example, the X direction). An inner circumferential surface of the attachment hole 13h of the electronic component 10M has a screw groove.

### (Attachment Portion 14)

The attachment portion 14 is a portion for fixing the electronic component 10M. The attachment portion 14 has an attachment hole 14h to which a fastening member 112 (for example, a screw or a bolt; and see FIG. 11) is attached. The attachment hole 14h penetrates the attachment portion 14 in the Z direction. The attachment hole 14h is an insertion hole through which the fastening member 112 passes. A fixing destination of the attachment portion 14 will be described later.

### <3.1.2 First-Type Connection Component 20M>

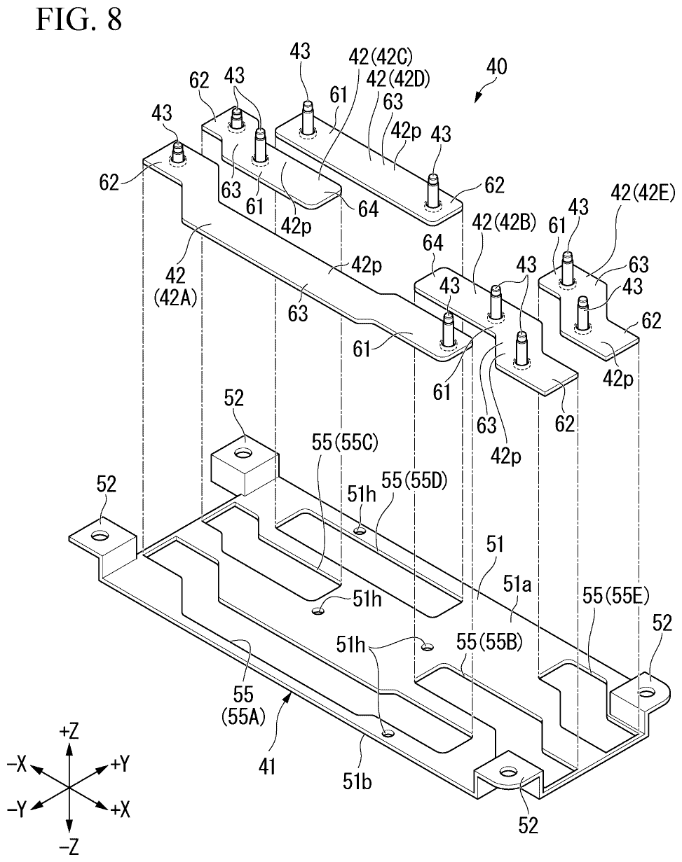

The first-type connection component 20M is a component that electrically connects the first-type electronic component 10M to the routing board 40. In the present embodiment, the connection component 20M electrically connects the electronic component 10M to the bus bar 42 (see FIG. 8) included in the routing board 40. The connection component 20M includes, for example, a first portion 21 and a second portion 22.

### (First Portion 21)

The first portion 21 of the connection component 20M is a portion connected to the terminal 13 of the electronic component 10M. The first portion 21 is a plate-shaped or prismatic portion extending in the Z direction. The first portion 21 extends in the Z direction along one end (for example, an end in the X direction) of the electronic component 10M. The first portion 21 is a standing portion that stands in the Z direction with respect to the routing board 40 (for example, with respect to a bus bar 42 that will be described later). The first portion 21 is adjacent to the electronic component 10M in the horizontal direction (for example, the X direction). For example, the first portion 21 is adjacent to the terminal 13 of the electronic component 10M in the horizontal direction (for example, the X direction), and is connected to the terminal 13 of the electronic component 10M from the horizontal direction (for example, the X direction).

The first portion 21 of the connection component 20M has a first attachment hole 21h through which the fastening member 71 (for example, a screw or a bolt) passes. The first attachment hole 21h is open in the horizontal direction (for example, the X direction). The fastening member 71 that has passed through the first attachment hole 21h is engaged with the electronic component 10M via the attachment hole 13h of the terminal 13, and thus the first portion 21 is physically and electrically connected to the terminal 13 of the electronic component 10M.

### (Second Portion 22)

The second portion 22 of the connection component 20M is a portion connected to the bus bar 42 (see FIG. 8). The second portion 22 protrudes in the horizontal direction (for example, the X direction) from end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20M is attached from the Z direction to the fastening member 43 (for example, a screw or a bolt; and see FIG. 8) protruding from the bus bar 42 in the +Z direction, and is physically and electrically connected to the bus bar 42. In the present embodiment, the second portion 22 of the connection component 20M has a second attachment hole 22h through which the fastening member 43 passes. The second attachment hole 22h is open in the Z direction. In the second portion 22, the fastening member 43 passes through the second attachment hole 22h. When the engagement member 44 (for example, a nut illustrated in FIG. 3) is engaged with the tip of the fastening member 43 passed through the second attachment hole 22h, the second portion 22 is fixed to the bus bar 42. In the present embodiment, the first portion 21 and the second portion 22 form one L-shaped connection component 20M.

### <3.1.3 Second-Type Electronic Component 10N>

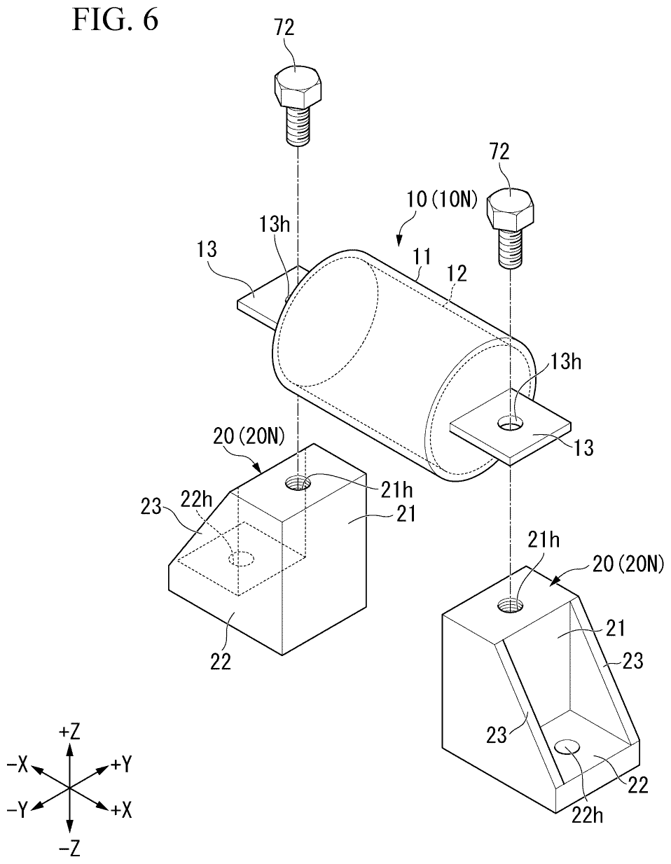

FIG. 6 is a perspective view illustrating the second-type electronic component 10N and the second-type connection component 20N.

As illustrated in FIG. 6, the second-type electronic component 10N is an electronic component in which two terminals 13 are separately disposed at both ends of the electronic component 10N in the horizontal direction. The electronic component 10N includes, for example, a case 11, a component body 12, and a plurality of terminals 13. Note that, among the constitutions of the electronic component 10N, constitutions having functions similar to those of the electronic component 10M are denoted by the same reference numbers. In this case, in the description regarding the electronic component 10N, the “electronic component 10M” may be replaced with the “electronic component 10N” in the description regarding the electronic component 10M described above.

In the electronic component 10N, the terminals 13 are disposed separately at both ends of the electronic component 10N in the horizontal direction (for example, the X direction). Each terminal 13 has an attachment hole 13h to which a fastening member 72 (for example, a screw or a bolt) is attached. The attachment hole 13h penetrates each terminal 13 in the Z direction. For example, the attachment hole 13h of the electronic component 10N is an insertion hole through which the fastening member 72 passes.

### <3.1.4 Second-Type Connection Component 20N>

The second-type connection component 20N is a component that electrically connects the second-type electronic component 10N and the routing board 40. In the present embodiment, the connection component 20N electrically connects the electronic component 10N to the bus bar 42 (see FIG. 8) included in the routing board 40. The connection component 20N includes, for example, a first portion 21, a second portion 22, and a third portion 23.

### (First Portion 21)

The first portion 21 of the connection component 20N is a portion connected to the terminal 13 of the electronic component 10N. The first portion 21 is a prismatic portion extending in the Z direction. The first portion 21 is a standing portion that stands in the Z direction with respect to the routing board 40 (for example, with respect to the bus bar 42). The first portion 21 is adjacent to the terminal 13 of the electronic component 10N in the Z direction, and is connected to the terminal 13 of the electronic component 10N from the Z direction. The first portion 21 of the connection component 20N has a first attachment hole 21h with which the fastening member 72 is engaged. The first attachment hole 21h is open on the +Z direction side in the first portion 21. An inner circumferential surface of the first attachment hole 21h of the connection component 20N has a screw groove. The fastening member 72 that has passed through the attachment hole 13h of the electronic component 10N is engaged with the first portion 21 via the attachment hole 21h of the first portion 21, and thus the first portion 21 is physically and electrically connected to the terminal 13 of the electronic component 10N.

### (Second Portion 22)

The second portion 22 of the connection component 20N is a portion connected to the bus bar 42 (see FIG. 8). The second portion 22 protrudes in the horizontal direction (for example, the X direction) from end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20N is attached from the Z direction to the fastening member 43 (for example, a screw or a bolt; and see FIG. 8) protruding from the bus bar 42 in the +Z direction, and is physically and electrically connected to the bus bar 42. In the present embodiment, the second portion 22 of the connection component 20N has a second attachment hole 22h through which the fastening member 43 passes. The second attachment hole 22h penetrates the second portion 22 in the Z direction. In the second portion 22, the fastening member 43 passes through the second attachment hole 22h. An engagement member 44 (for example, a nut; and see FIG. 3) is engaged with the tip of the fastening member 43 that has passed through the second attachment hole 22h, and thus the second portion 22 is fixed to the bus bar 42.

### (Third Portion 23)

The third portion 23 is a standing wall (side wall) standing in the +Z direction from both ends of the second portion 22 in the horizontal direction. The third portion 23 is a wall provided in the Z direction. The third portion 23 is connected to the first portion 21 and is also connected to the second portion 22. For example, the third portion 23 extends obliquely so as to increase in the X direction as it advances in the −Z direction. The third portion 23 may be provided in the connection component 20M. On the other hand, the connection component 20N need not have the third portion 23.

### <3.2 Connection Component 30 for External Connection>

Next, the connection component 30 for external connection will be described.

As illustrated in FIGS. 3 and 4, the connection component 30 is a component that electrically connects the external connection bus bar 76 to the routing board 40. In the present embodiment, the connection component 30 electrically connects the external connection bus bar 76 to the bus bar 42 included in the routing board 40. The external connection bus bar 76 is electrically connected to an external device. In the present disclosure, the “external device” is an electrical device existing outside the electrical connection unit 1. The external device is, for example, a battery unit mounted on a vehicle or an inverter for driving a motor of a vehicle. However, the external device is not limited to a battery unit or an inverter. The bus bar 42 is an example of a “resistor”.

Similarly to the connection component 20, the connection component 30 is made of a metal (for example, copper or a copper alloy). As illustrated in FIG. 2, the connection component 30 is provided in a state of standing on the +Z direction side at the outer peripheral portion (the end on the X direction side) of the routing board 40M. A first end (an end on the −Z direction side) of the connection component 30 is connected to the bus bar 42 via a fastening member 43 (for example, a bolt). A second end (an end on the +Z direction side) of the connection component 20 is connected to the external connection bus bar 76 via a fastening member 73 (for example, a screw or a bolt).

### <3.3 Connection Component 100 for Unit Connection>

Next, the connection component 100 for unit connection will be described.

As illustrated in FIG. 2, the connection component 100 electrically connects the adjacent subunits SU. In the present embodiment, the connection component 100 connects the bus bar 42 included in one subunit SU (for example, the second subunit SUY) to the bus bar 42 included in the other subunit SU (for example, the third subunit SUZ) among the adjacent subunits SU.

### <3.4 Routing Board 40>

First, the routing board 40 will be described.

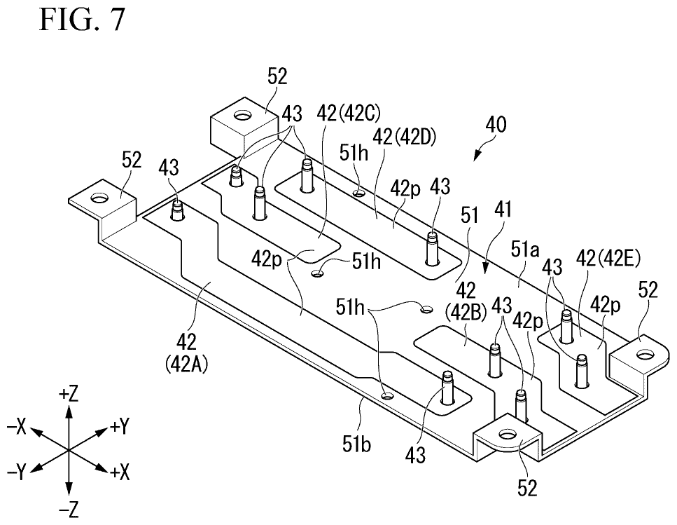

FIG. 7 is a perspective view illustrating the routing board 40.

As illustrated in FIG. 7, the routing board 40 is a member that forms at least part of an energization path between the plurality of electronic components 10 and/or at least part of an energization path between the electronic component 10 and an external device. In the present disclosure, the “routing board” indicates a board-type routing structure. The “board type” indicates a plate shape along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following the thickness of the bus bar is present on the surface, and the like. In the present embodiment, the routing board 40 has a plate shape formed in the X direction and the Y direction.

The routing board 40 includes, for example, a base plate 41, one or more (for example, a plurality of) bus bars 42, and a plurality of fastening members 43. In the present embodiment, the base plate 41 and the plurality of bus bars 42 are integrated through insert molding. For example, the routing board 40 is formed as a single member by insert-molding the bus bar 42 with the base plate 41 after the fastening member 43 is fixed to the bus bar 42. That is, the bus bar 42 is integrated with the base plate 41 without using a fastening member such as a screw or a bolt. Note that the routing board 40 may be formed by another structure instead of the insert molding.

FIG. 8 is a partially exploded perspective view of the routing board 40. Hereinafter, for convenience of description, the base plate 41, the bus bars 42, and the fastening members 43 will be described with reference to the drawings in which the routing board 40 is partially exploded.

### (Base Plate 41)

As illustrated in FIG. 8, the base plate 41 is a holding member that integrally holds the plurality of bus bars 42 arranged in the horizontal direction at intervals. The base plate 41 is made of, for example, synthetic resin and has an insulating property. The base plate 41 is formed in, for example, a rectangular shape in which the X direction is a longitudinal direction and the Y direction is a lateral direction. The base plate 41 electrically insulates the plurality of bus bars 42 from each other. The base plate 41 includes, for example, a flat surface portion 51 and a plurality of fixing portions 52.

The flat surface portion 51 is a portion formed in a plate shape in the base plate 41. The flat surface portion 51 forms a main portion of the base plate 41. The flat surface portion 51 spreads in the horizontal direction. In the present embodiment, the flat surface portion 51 extends over the entire width in the X direction of the base plate 41 and over the entire width in the Y direction of the base plate 41 except for the four corner portions of the base plate 41.

The flat surface portion 51 has a first surface 51a and a second surface 51b. The first surface 51a is a surface directed toward the +Z direction side. The first surface 51a is a flat surface provided in the horizontal direction. The first surface 51a faces the plurality of electronic components 10 and faces the insulating cover 93 (see FIG. 1) of the electrical connection unit 1. The second surface 51b is located on the side opposite to the first surface 51a. The second surface 51b is a surface directed toward the −Z direction side. The second surface 51b is a flat surface provided in the horizontal direction. The second surface 51b faces the metal plate 80 (see FIG. 1). A thickness direction (plate thickness direction) of the flat surface portion 51 is the Z direction.

In the flat surface portion 51, for example, one or more (for example, a plurality of) accommodation portions 55 in which the bus bars 42 are accommodated are formed. The plurality of accommodation portions 55 are formed apart from each other in the X direction or the Y direction. Each of the accommodation portions 55 is, for example, a through-hole penetrating the flat surface portion 51 in the Z direction. That is, each accommodation portion 55 is open in the Z direction on both the first surface 51a and the second surface 51b. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates the flat surface portion in the first direction (Z direction)” may include a case where part of the entire length of the accommodation portion 55 penetrates the flat surface portion 51 in the Z direction (for example, the remaining portion of the accommodation portion 55 may be a recess recessed in the Z direction, or may be provided inside the base plate 41 and not exposed to the outside of the base plate 41). Similarly, in the present disclosure, the phrase “the accommodation portion is recessed in the first direction (Z direction)” may include a case where part of the entire length of the accommodation portion 55 is recessed in the Z direction (for example, a remaining portion of the accommodation portion 55 may be a through-hole penetrating the flat surface portion 51 in the Z direction, or may be provided inside the base plate 41 and not exposed to the outside of the base plate 41).

As illustrated in FIG. 8, each accommodation portion 55 is formed in an outer shape corresponding to the shape of the accommodated bus bar 42 when viewed from the Z direction. In the present embodiment, the flat surface portion 51 includes, for example, five accommodation portions 55A, 55B, 55C, 55D, and 55E as the plurality of accommodation portions 55.

In the flat surface portion 51, a through-hole 51h is formed at a position shifted in the X direction or the Y direction with respect to the accommodation portion 55. As illustrated in FIG. 4, the through-hole 51h is formed, for example, at a position overlapping the attachment portion 14 of the electronic component 10 when viewed from the Z direction. The attachment portion 14 is a portion for attaching the electronic component 10 to the metal plate 80. The attachment portion 14 protrudes in the X direction or the Y direction from a −Z direction-side end of the case of the electronic component 10.

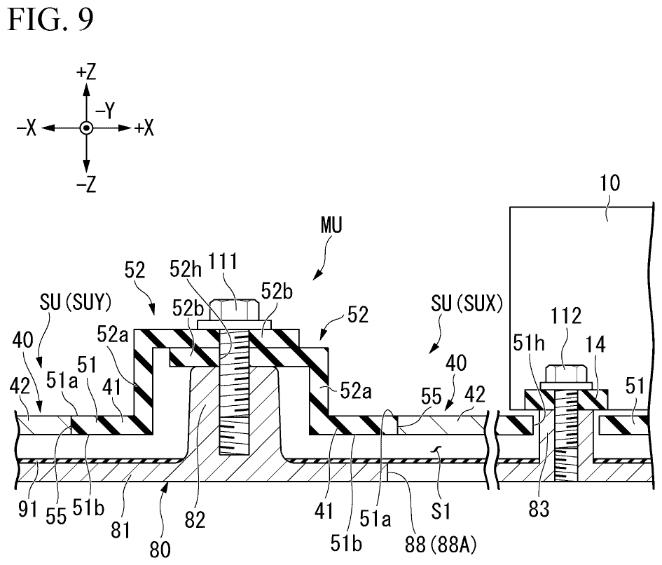

FIG. 9 is a cross-sectional view taken along line F9-F9 in FIG. 4.

As illustrated in FIGS. 4 and 9, the fixing portion 52 is a portion used for fixing the metal plate 80 and the base plate 41. The fixing portion 52 is provided at a corner portion of the base plate 41. The fixing portion 52 includes, for example, a standing plate portion 52a and a horizontal plate portion 52b.

The standing plate portion 52a stands on the +Z direction side from the end of the flat surface portion 51 of the base plate 41. The standing plate portion 52a is formed in, for example, an L shape when viewed from the Z direction. That is, the standing plate portion 52a extends in the Z direction in a state in which a part thereof in the horizontal direction is open.

The horizontal plate portion 52b extends in the horizontal direction from the end of the standing plate portion 52a on the +Z direction side. The horizontal plate portion 52b is a plate portion provided in the horizontal direction. The horizontal plate portion 52b extends in an eaves shape to cover a portion surrounded by the standing plate portion 52a from the +Z direction side.

### (Bus Bar 42)

As illustrated in FIGS. 5 and 6, the bus bar 42 is a routing member (electrical connection member) included in the routing board 40. The bus bar 42 is, for example, a routing member for electrically connecting the plurality of electronic components 10 to each other. The bus bar 42 may be a routing member for connecting one electronic component 10 to an external device. The bus bar 42 is made of a metal (for example, copper or a copper alloy) and has conductivity. In the present embodiment, the routing board 40 includes, for example, five bus bars 42A, 42B, 42C, 42D, 42E as the plurality of bus bars 42. The five bus bars 42A, 42B, 42C, 42D, and 42E are disposed to be arranged in the horizontal direction at intervals. The five bus bars 42A, 42B, 42C, 42D, and 42E are held by the flat surface portion 51 of the base plate 41.

At least part of each bus bar 42 has a plate shape formed in the horizontal direction. At least part of each bus bar 42 extends along the flat surface portion 51 in a state of being accommodated in the accommodation portion 55. At least part of each bus bar 42 extends along the first surface 51a of the flat surface portion 51. At least part of each bus bar 42 extends in the horizontal direction in the accommodation portion 55. In the present embodiment, each bus bar 42 has a plate shape formed in the horizontal direction over the entire bus bar 42. Each of the bus bars 42 extends along the flat surface portion 51 in a state of being accommodated in the accommodation portion 55 over the entire length of the bus bar 42. Hereinafter, in each bus bar 42, a portion accommodated in the accommodation portion 55 (a portion extending along the flat surface portion 51) may be referred to as a “plate portion 42p”.

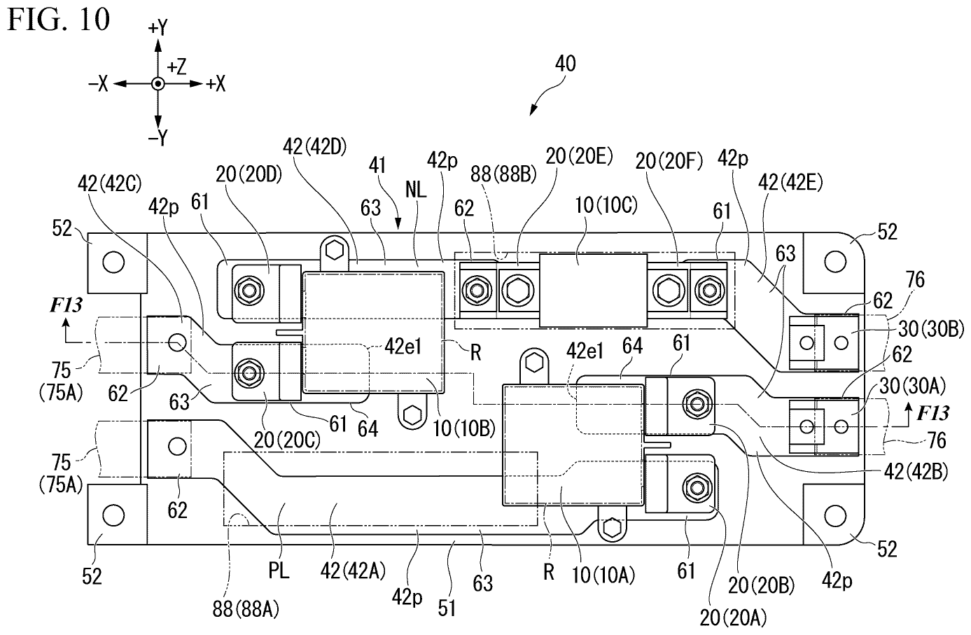

FIG. 10 is a plan view illustrating the routing board 40.

As illustrated in FIG. 10, the plate portion 42p of each bus bar 42 includes, for example, a first connection portion 61, a second connection portion 62, and an extending portion 63.

The first connection portion 61 is a portion in contact with one connection component 20 (hereinafter referred to as a “first connection component 20”) among the plurality of connection components 20. The first connection component 20 is a connection component that connects one electronic component 10 (hereinafter referred to as a “first electronic component 10”) among the plurality of electronic components 10 to the bus bar 42. The first connection portion 61 is a portion of the bus bar 42 overlapping the first connection component 20 when viewed from the Z direction. The first connection portion 61 is adjacent to the first connection component 20 in the Z direction. The first connection portion 61 is connected to the first connection component 20 from the Z direction.

The second connection portion 62 is a portion in contact with the connection component 20 (hereinafter referred to as a “second connection component 20”) different from the first connection component 20 among the plurality of connection components 20. The second connection component 20 is a connection component that connects the electronic component 10 (hereinafter referred to as a “second electronic component 10”) different from the first electronic component 10 among the plurality of electronic components 10 to the bus bar 42. The second connection portion 62 is a portion of the bus bar 42 overlapping the second connection component 20 when viewed from the Z direction. The second connection portion 62 is adjacent to the second connection component 20 in the Z direction. The second connection portion 62 is connected to the second connection component 20 from the Z direction.

The second connection portion 62 may be a portion in contact with the connection component 30. The connection component 30 is a connection component for connecting an external device to the bus bar 42. In this case, the second connection portion 62 is a portion of the bus bar 42 overlapping the connection component 30 when viewed from the Z direction. The second connection portion 62 is adjacent to the connection component 30 in the Z direction. The second connection portion 62 is connected to the connection component 30 from the Z direction.

The second connection portion 62 may be a portion in contact with the coupling bus bar 75 for connection with another subunit SU instead of the connection components 20 and 30. In this case, the second connection portion 62 is a portion of the bus bar 42 that overlaps the coupling bus bar 75 when viewed from the Z direction. The second connection portion 62 is adjacent to the coupling bus bar 75 in the Z direction. The second connection portion 62 is connected to the coupling bus bar 75 from the Z direction.

The extending portion 63 extends from the first connection portion 61 in the X direction or the Y direction. The extending portion 63 is provided between the first connection portion 61 and the second connection portion 62. The extending portion 63 extends over the first connection portion 61 and the second connection portion 62. The extending portion 63 connects the first connection portion 61 to the second connection portion 62.

In the present embodiment, the first connection portion 61, the second connection portion 62, and the extending portion 63 have a plate shape formed in the horizontal direction. In the present embodiment, each bus bar 42 extends along the flat surface portion 51 in a state of being accommodated in the accommodation portion 55 at least over the first connection portion 61 and the second connection portion 62. For example, the first connection portion 61, the second connection portion 62, and the extending portion 63 extend along the flat surface portion 51 in a state of being accommodated in the accommodation portion 55. A portion of each bus bar 42 accommodated in the accommodation portion 55 is exposed on the first surface 51a and the second surface 51b of the flat surface portion 51. That is, the surface of each bus bar 42 directed in the Z direction is exposed to the outside of the base plate 41 (for example, in the +Z direction and the −Z direction) through the opening of the accommodation portion 55. However, part of the bus bar 42 may be buried in the base plate 41.

In the present embodiment, the extending portions 63 of some of the bus bars 42 are accommodated in the accommodation portion 55 to extend over both sides of a region R through the region R overlapping the electronic component 10 when viewed from the Z direction. For example, the extending portion 63 extends linearly in the X direction. The extending portion 63 extends over a region R overlapping the electronic component 10 when viewed from the Z direction, over the +X direction side and the −X direction side of the region R.

The one or more bus bars 42 may have an extension 64 in addition to the first connection portion 61, the second connection portion 62, and the extending portion 63. The extension 64 is a portion where the bus bar 42 extends for the purpose of increasing a heat dissipation area and/or increasing a heat capacity for heat storage (heat absorption). The extension 64 is a portion that is not used for electrical connection. For example, the extension 64 is located on the side opposite to the extending portion 63 with respect to the first connection portion 61 (or the second connection portion 62). The extension 64 has a plate shape formed in the horizontal direction. The extension 64 extends along the flat surface portion 51 in a state of being accommodated in the accommodation portion 55. The extension 64 is accommodated in the accommodation portion 55 to extend to the region R overlapping the electronic component 10 when viewed from the Z direction. The extension 64 has an end 42e1 of the bus bar 42 at a position overlapping the region R when viewed from the Z direction.

Some routing examples of the bus bar 42 will be described below. The plurality of electronic components 10 include three electronic components 10A, 10B, and 10C. The plurality of connection components 20 include six connection components 20A, 20B, 20C, 20D, 20E, and 20F. The plurality of connection components 30 include two connection components 30A and 30B.

### (First Routing Example)

First, a routing example related to the bus bar 42A will be described.

The bus bar 42A includes a first connection portion 61, a second connection portion 62, and an extending portion 63. The first connection portion 61 is located on the +X direction side with respect to the electronic component 10A when viewed from the Z direction. The first connection portion 61 is electrically connected to the terminal 13 (for example, a positive electrode terminal; and see FIG. 5) of the electronic component 10A via the connection component 20A. The second connection portion 62 is located on the −X direction side with respect to the electronic component 10A when viewed from the Z direction. The second connection portion 62 is electrically connected to another subunit SU via the coupling bus bar 75.

The extending portion 63 is accommodated in the accommodation portion 55 to extend over both sides of the region R through the region R overlapping the electronic component 10A when viewed from the Z direction. For example, the extending portion 63 extends linearly in the X direction. The extending portion 63 extends over the region R overlapping the electronic component 10A when viewed from the Z direction, over the +X direction side and the −X direction side of the region R. The bus bar 42A is, for example, a bus bar included in the positive electrode line PL included in the electrical connection unit 1.

### (Second Routing Example)

Next, a routing example related to the bus bar 42B will be described.

The bus bar 42B has a first connection portion 61, a second connection portion 62, an extending portion 63, and an extension 64. The first connection portion 61 is electrically connected to the terminal 13 (for example, a negative electrode terminal; and see FIG. 5) of the electronic component 10A via the connection component 20B different from the first connection component 20. The second connection portion 62 is electrically connected to the external connection bus bar 76 via the connection component 30A. The extension 64 extends to the region R overlapping the electronic component 10A when viewed from the Z direction. The extension 64 has an end 42e1 of the bus bar 42 at a position overlapping the region R when viewed from the Z direction. Note that the extending portion 63 of the bus bar 42B may extend over both sides of the region R through the region R overlapping the electronic component 10 when viewed from the Z direction, similarly to the extending portion 63 of the bus bar 42A. The bus bar 42B is, for example, a bus bar included in the positive electrode line PL included in the electrical connection unit 1.

### (Third Routing Example)

Next, a routing example related to the bus bar 42C will be described.

The bus bar 42C includes a first connection portion 61, a second connection portion 62, an extending portion 63, and an extension 64. The first connection portion 61 is electrically connected to the terminal 13 (for example, a negative electrode terminal; and see FIG. 5) of the electronic component 10B via the connection component 20C. The second connection portion 62 is electrically connected to another subunit SU via the coupling bus bar 75. The extension 64 extends to a region R overlapping the electronic component 10B when viewed from the Z direction. In the extension 64, the bus bar 42C having the end 42e1 of the bus bar 42 at a position overlapping the region R when viewed from the Z direction is, for example, a bus bar included in a negative electrode line NL of the electrical connection unit 1.

### (Fourth Routing Example)

Next, a routing example related to the bus bar 42D will be described.

The bus bar 42D has a first connection portion 61, a second connection portion 62, and an extending portion 63. The first connection portion 61 is electrically connected to the terminal 13 (for example, a positive electrode terminal; and see FIG. 5) of the electronic component 10B via the connection component 20D. The second connection portion 62 is electrically connected to the terminal 13 (for example, a negative electrode terminal; and see FIG. 6) of the electronic component 10C via the connection component 20E. The bus bar 42D is, for example, a bus bar included in the negative electrode line NL included in the electrical connection unit 1.

### (Fifth Routing Example)

Next, a routing example related to the bus bar 42E will be described.

The bus bar 42E includes a first connection portion 61, a second connection portion 62, and an extending portion 63. The first connection portion 61 is electrically connected to the terminal 13 (for example, a negative electrode terminal; and see FIG. 6) of the electronic component 10C via the connection component 20F. The second connection portion 62 is electrically connected to the external connection bus bar 76 via the connection component 30B. The bus bar 42E is, for example, a bus bar included in the negative electrode line NL included in the electrical connection unit 1. In the present embodiment, the electronic component 10C (second-type electronic component 10N) is bridged between the connection components 20D and 20F (second-type connection component 20N). Specifically, as illustrated in FIGS. 6 and 10, the electronic component 10C is supported by the connection components 20D and 20F in a state in which the case 11 is separated from the routing board 40 in the Z direction by both the terminals 13 being supported by the first portion 21 from the +Z direction side.

### (Fastening Member 43)

Next, referring to FIG. 8 again, the fastening member 43 will be described.

The fastening member 43 is a component for fixing the bus bar 42 and a connection target component (the connection component 20, the connection component 30, or the coupling bus bar 75) of the bus bar 42. The fastening member 43 is, for example, a caulking bolt fixed to the bus bar 42. The fastening member 43 penetrates the bus bar 42 in the Z direction. The fastening member 43 is electrically and physically connected to the bus bar 42 in a state of protruding toward the +Z direction side from the bus bar 42. Note that the fastening member 43 is not limited to caulking fixation and may be fixed to the bus bar 42 through welding or other methods.

The connection component 20 is fixed to the fastening member 43 while being previously fixed to the electronic component 10 via the fastening member 71 or the fastening member 72. For example, the fastening member 43 penetrates the second portion 22 (see FIGS. 5 and 6) of the connection component 20. As illustrated in FIG. 3, an engagement member 44 (for example, a nut) is attached to a portion of the fastening member 43 protruding toward the +Z direction side from the connection component 20. With this attachment, the connection component 20 is mounted on the routing board 40. In the present disclosure, the phrase “an electronic component is mounted on a board” is not limited to a case where the electronic component is directly connected to the board, and includes a case where the electronic component is connected to the board via another component (for example, the connection component 20). In the present disclosure, the phrase “an electronic component is mounted on a board” indicates that at least the electronic component is electrically connected to the board, and includes a case where the electronic component is fixed to a member (for example, the metal plate 80) different from the board instead of/in addition to the board.

### 4. Connection Structure

Next, a connection structure of the subunit SU will be described.

As illustrated in FIG. 2, the first subunit SUX, the second subunit SUY, and the third subunit SUZ are arranged in this order from the +X direction side to the −X direction side. The first subunit SUX and the second subunit SUY are electrically connected via a coupling bus bar 75A. The second subunit SUY and the third subunit SUZ are electrically and physically connected via a coupling bus bar 75B.

The adjacent subunits SU are disposed in a state in which the ends facing each other in the X direction overlap each other in the Z direction. Specifically, the fixing portion 52 (horizontal plate portion 52b) located on the +X direction side in the second subunit SUY overlaps the fixing portion 52 (horizontal plate portion 52b) located on the −X direction side in the first subunit SUX from the +Z direction side. The fixing portion 52 (horizontal plate portion 52b) located on the −X direction side in the second subunit SUY overlaps the fixing portion 52 (horizontal plate portion 52b) located on the +X direction side in the third subunit SUX from the +Z direction side.

### 5. Metal Plate 80, Insulating Sheet 91, Heat Transfer Member 92, and Insulating Cover 93

Next, the metal plate 80, the insulating sheet 91, the heat transfer member 92, and the insulating cover 93 will be described.

### <5.1 Metal Plate 80>

FIG. 11 is a partially exploded perspective view of the electrical connection unit 1.

As illustrated in FIG. 11, the metal plate 80 is a member for securing the rigidity of the electrical connection unit 1 and enhancing the heat dissipation property of the electrical connection unit 1. The metal plate 80 is made of a metal (for example, aluminum or an aluminum alloy). The metal plate 80 is an example of a “heat dissipation plate”. The heat dissipation plate is not limited to a metal, and various materials can be applied as long as the heat dissipation plate is made of a material superior in thermal conductivity to the base plate 41, for example.

The metal plate 80 has a rectangular shape formed in the X direction when viewed from the Z direction. The metal plate 80 has a first end 80e1, a second end 80e2, a third end 80e3, and a fourth end 80e4. The first end 80e1 and the second end 80e2 are a pair of ends of the metal plate 80 in the longitudinal direction, and are separated in the X direction. The third end 80e3 and the fourth end 80e4 are a pair of ends of the metal plate 80 in the lateral direction, and are separated in the Y direction. In the present embodiment, the metal plate 80 has a size that covers the entire three subunits SU (main body MU) from below. Specifically, the length of the metal plate 80 in the X direction is larger than the length of the main body MU in the X direction. The length of the metal plate 80 in the Y direction is larger than the length of the main body MU in the Y direction. Therefore, when viewed from the Z direction, the area of the metal plate 80 is larger than the area of the main body MU.

The metal plate 80 includes, for example, a flat surface portion 81, a plurality of fixing portions 82, a plurality of fixing portions 83, and a peripheral wall portion 84.

The flat surface portion 81 is a portion formed in a plate shape in the metal plate 80. The flat surface portion 81 has a plate shape formed in the horizontal direction. The flat surface portion 81 forms a main portion of the metal plate 80. The flat surface portion 81 forms a base portion (metal base portion) of the metal plate 80. In the present embodiment, the flat surface portion 81 has a size that covers the entire three subunits SU (main body MU) from below. The flat surface portion 81 faces the routing boards 40 of the three subunits SU. In the present embodiment, the metal plate 80 faces the second surface 51b of each subunit SU with a gap S1 (see FIG. 9) between the metal plate 80 and the flat surface portion 51 (second surface 51b) of each subunit SU. Note that an attachment flange or the like attached to an external device may be provided in an outer peripheral portion of the flat surface portion 81 (a position not overlapping the routing board 40 when viewed from the Z direction).

As illustrated in FIGS. 9 and 11, the fixing portion 82 is a portion for fixing the base plate 41 of each subunit SU to the metal plate 80. The fixing portion 82 is provided at a position corresponding to the fixing portion 52 of each subunit SU when viewed from the Z direction. The fixing portion 82 is a cylindrical or prismatic boss protruding in the +Z direction from the flat surface portion 81 of the metal plate 80.

The fixing portion 83 is a portion for directly fixing the electronic component 10 of each subunit SU to the metal plate 80 without using the base plate 41. The fixing portion 83 is provided at a position corresponding to the attachment portion 14 of the electronic component 10 of each subunit SU when viewed from the Z direction. The fixing portion 83 is a cylindrical or prismatic boss protruding in the +Z direction from the flat surface portion 81. The amount of protrusion of the fixing portion 83 in the Z direction is smaller than the amount of protrusion of the fixing portion 82 in the Z direction.

As illustrated in FIG. 2, the peripheral wall portion 84 extends from the outer peripheral edge of the flat surface portion 81 toward the +Z direction side. The peripheral wall portion 84 extends over the entire periphery of the flat surface portion 81. The length of the peripheral wall portion 84 in the Z direction is shorter than the lengths of the fixing portions 82 and 83 in the Z direction.

### <5.2 Insulating Sheet 91>

The insulating sheet 91 is an insulating member for electrically insulating the metal plate 80 and the bus bars 42 of each subunit SU. The insulating sheet 91 is made of, for example, a synthetic resin such as polyester or polyimide, and has an insulating property. The insulating sheet 91 has a rectangular shape when viewed from the Z direction. The insulating sheet 91 is provided to cover the entire flat surface portion 81 of the metal plate 80 from the +Z direction side. Therefore, the main body MU faces the metal plate 80 with the insulating sheet 91 interposed therebetween.

The insulating sheet 91 is attached to the flat surface portion 81 of the metal plate 80. A notch or an opening for avoiding the fixing portion 82 and the fixing portion 83 of the metal plate 80 is formed in the insulating sheet 91. In the present embodiment, the thickness of the insulating sheet 91 in the Z direction is smaller than the thickness of the peripheral wall portion 84 in the Z direction. Therefore, the insulating sheet 91 is positioned in the horizontal direction with respect to the metal plate 80 by being surrounded by the peripheral wall portion 84.

### <5.3 Heat Transfer Member 92>

As illustrated in FIG. 9, the heat transfer member 92 is a member for transferring heat generated by the electronic component 10 at the time of energization and/or heat generated by the bus bar 42 itself at the time of energization to the metal plate 80. The heat transfer member 92 is, for example, a heat transfer sheet (for example, a thermally conductive silicone sheet) having elasticity. However, the heat transfer member 92 is not limited to the above example, and may be a heat transfer member made of a thermally conductive gel or another material.

The plurality of heat transfer members 92 include, for example, one or more (for example, a plurality of) heat transfer members 92 corresponding to the first subunit SUX, one or more (for example, a plurality of) heat transfer members 92 corresponding to the second subunit SUY, and one or more (for example, a plurality of) heat transfer members 92 corresponding to the third subunit SUZ. The heat transfer member 92 corresponding to the first subunit SUX is disposed at a position overlapping the first subunit SUX when viewed from the Z direction, and transfers heat generated by the first subunit SUX to the metal plate 80. The heat transfer member 92 corresponding to the second subunit SUY is disposed at a position overlapping the second subunit SUY when viewed from the Z direction, and transfers heat generated by the second subunit SUY to the metal plate 80. The heat transfer member 92 corresponding to the third subunit SUZ is disposed at a position overlapping the third subunit SUZ when viewed from the Z direction, and transfers heat generated by the third subunit SUZ to the metal plate 80.

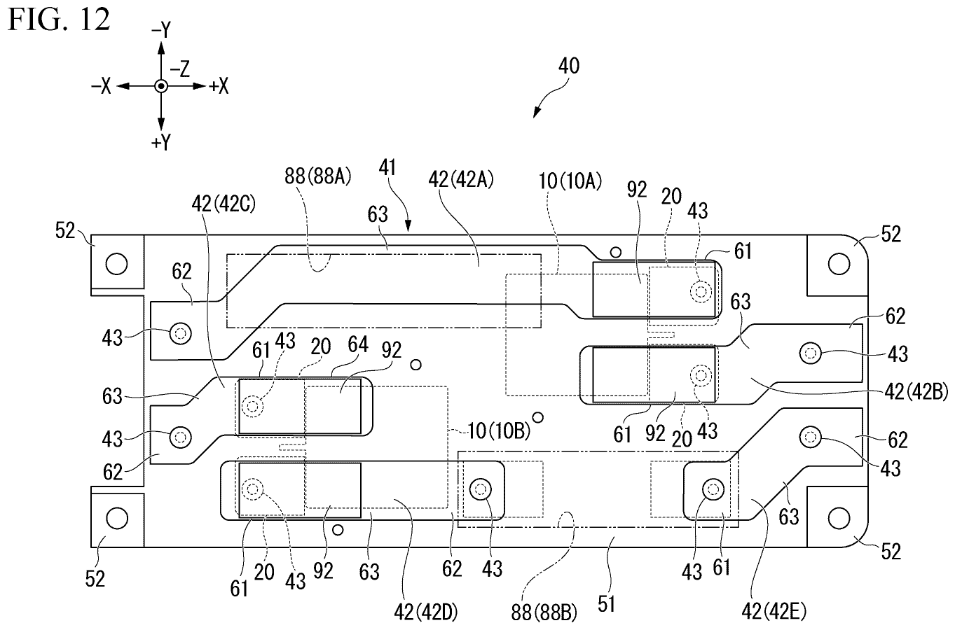

FIG. 12 is a bottom view illustrating the routing board 40.

As illustrated in FIG. 12, the heat transfer member 92 transfers heat transferred from the electronic component 10 to the bus bar 42 and/or heat generated in the bus bar 42 from the bus bar 42 to the metal plate 80. The plurality of heat transfer members 92 are partially provided in the routing board 40 in the horizontal direction. For example, the plurality of heat transfer members 92 are disposed at positions overlapping part of the bus bar 42 in the routing board 40 when viewed from the Z direction. The plurality of heat transfer members 92 are disposed at positions overlapping part of bus bar 42 in the vicinity of electronic components 10 (for example, the electronic components 10A and 10B) when viewed from the Z direction. In the present embodiment, the plurality of heat transfer members 92 are disposed at positions overlapping the connection component 20 (a connection portion between the bus bar 42 and the electronic component 10) when viewed from the Z direction.

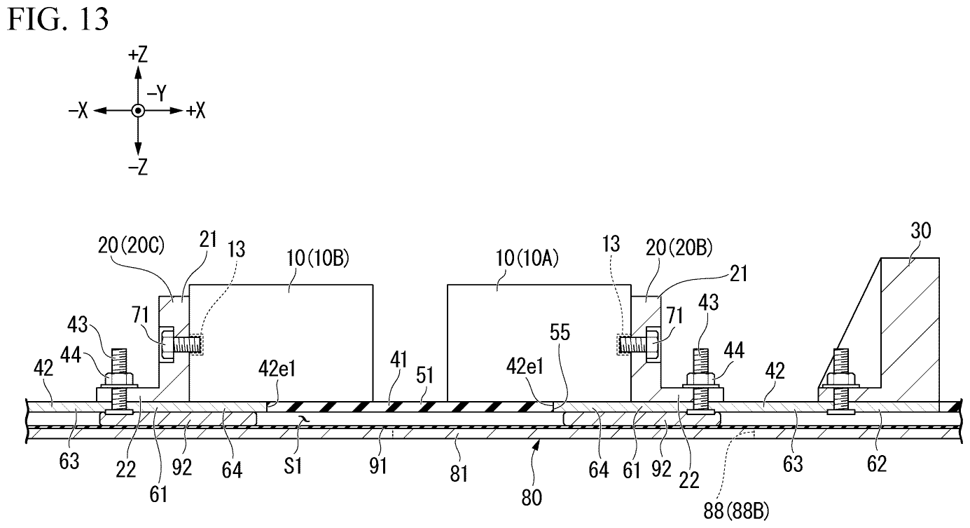

FIG. 13 is a cross-sectional view taken along line F13-F13 of the structure illustrated in FIG. 10.

As illustrated in FIG. 13, the heat transfer member 92 is provided in a crushed state between the main body MU and the insulating sheet 91 in the Z direction. A portion of the heat transfer member 92 located on the −Z direction side is in contact with the metal plate 80 via the insulating sheet 91. The heat transfer member 92 may be provided between the insulating sheet 91 and the metal plate 80.

A portion of the heat transfer member 92 located on the +Z direction side is in contact with the bus bar 42. In the present embodiment, the heat transfer member 92 is in contact with the bus bar 42 at a position overlapping the connection component 20 when viewed from the Z direction. In this case, the heat transfer member 92 easily transfers the heat transferred from the electronic component 10 to the connection component 20 from the connection component 20 to the metal plate 80 via the bus bar 42. Part of the heat transfer member 92 is disposed at a position overlapping the fastening member 43 when viewed from the Z direction, and is in contact with the fastening member 43. In this case, the heat transfer member 92 easily transfers the heat transferred from the electronic component 10 to the connection component 20 from the fastening member 43 to the metal plate 80.

In the present embodiment, part of the heat transfer member 92 is in contact with the bus bar 42 at a position overlapping the electronic component 10 when viewed from the Z direction. In this case, the heat transfer member 92 easily transfers the heat transferred from the electronic component 10 to the bus bar 42 from the bus bar 42 to the metal plate 80. In the example illustrated in FIG. 11, the upper surface of the bus bar 42 is in contact with the electronic component 10, and thus the bus bar 42 is thermally connected to the electronic component 10. Note that the bus bar 42 may be thermally connected to the electronic component 10 at the extending portion 63 or the extension 64. The electronic component 10, the connection component 20, and the bus bar 42 are examples of a “first resistor”.

### <5.4 Insulating Cover 93>

Referring to FIG. 1 again, the insulating cover 93 will be described. The insulating cover 93 is a member for securing safety of the main body MU with respect to the energization path. The insulating cover 93 is made of, for example, a synthetic resin and has an insulating property. The insulating cover 93 has, for example, a box shape that is open on the −Z direction side. The insulating cover 93 is attached to the metal plate 80 to cover the main body MU from the +Z direction side. In the present embodiment, a plurality of vent holes 93h are formed in the top wall of the insulating cover 93. Note that the insulating cover 93 is not limited to a box-shaped member, and may be a sheet-shaped member that covers the energization path of the main body MU.

### 6. Fixing Structure

Next, a fixing structure of the subunit SU will be described.

As illustrated in FIG. 7, the main body MU is stacked on the metal plate 80 in the Z direction in a state in which the fixing portions 52 of the adjacent subunits SU overlap the fixing portion 82 of the metal plate 80. The fixing portions 52 and 82 overlapping each other in the Z direction are fixed to each other via the fastening member 111 (for example, a screw or a bolt). The fastening member 111 penetrates the fixing portion 52 of the subunit SU and is then fastened to the fixing portion 82 of the metal plate 80.

In a state in which the main body MU and the metal plate 80 are stacked, the fixing portion 83 of the metal plate 80 penetrates the through-hole 51h of the subunit SU. The attachment portion 14 of the electronic component 10 overlaps the fixing portion 83 in the Z direction. The attachment portion 14 and the fixing portion 83 overlapping each other in the Z direction are fixed to each other via a fastening member 112 (for example, a screw or a bolt). The fastening member 112 penetrates the attachment portion 14 and is then fastened to the fixing portion 83 of the metal plate 80. A gap through which air can pass is provided between the inner circumferential surface of the through-hole 51h and the fixing portion 83.

### 7. Weight Reduction Portion 88

Next, a weight reduction portion 88 formed on the metal plate 80 will be described.

As illustrated in FIG. 11, one or more (for example, a plurality of) weight reduction portions 88 are formed in portions of the flat surface portion 81 of the metal plate 80 where the fixing portions 82 and 83 are avoided. As illustrated in FIG. 9, the weight reduction portion 88 is a through-hole penetrating the flat surface portion 81 in the Z direction.

The weight reduction portion 88 is provided to correspond to each subunit SU. That is, the weight reduction portion 88 is provided at each position of the metal plate 80 overlapping the subunit SU when viewed from the Z direction. In the present embodiment, the weight reduction portions 88 are arranged in the X direction at both ends of the metal plate 80 in the Y direction at intervals. In the following description, by taking the weight reduction portion 88 provided to correspond to the first subunit SUX as an example, the weight reduction portion 88 will be described in detail.

As illustrated in FIG. 12, each of the weight reduction portions 88 is formed at a position overlapping the routing board 40 and not overlapping at least part of the heat transfer member 92 in the flat surface portion 81 when viewed from the Z direction. In the present embodiment, each of the weight reduction portions 88 is provided at a position shifted with respect to the entire heat transfer member 92 when viewed from the Z direction. The weight reduction portions 88 include weight reduction portions 88A and 88B. The weight reduction portions 88A and 88B are disposed apart from each other in the horizontal direction.

As illustrated in FIGS. 9 and 10, the weight reduction portion 88A is provided at a position overlapping the bus bar 42A in the flat surface portion 81 when viewed from the Z direction. In the present embodiment, part of the weight reduction portion 88A overlaps the extending portion 63 when viewed from the Z direction. That is, part of the weight reduction portion 88A overlaps the bus bar 42A, and the rest thereof overlaps the flat surface portion 51. However, the entire weight reduction portion 88A may overlap the bus bar 42A or the flat surface portion 51.

The weight reduction portion 88A is formed in a rectangular shape having the X direction as a longitudinal direction and the Y direction as a lateral direction when viewed from the Z direction. The weight reduction portion 88A linearly extends in the extending direction of the bus bar 42A (extending portion 63). The length of the weight reduction portion 88A in the X direction is shorter than the length of the bus bar 42A in the X direction. The width of the weight reduction portion 88A in the Y direction is smaller than the width of the extending portion 63 in the Y direction. However, a size or a shape of the weight reduction portion 88A may be changed as appropriate.

As illustrated in FIGS. 10 and 13, the weight reduction portion 88B is provided at a position overlapping the electronic component 10C and the connection components 20E and 20F when viewed from the Z direction in the flat surface portion 81. The weight reduction portion 88B is formed in a rectangular shape having the X direction as a longitudinal direction and the Y direction as a lateral direction when viewed from the Z direction. In the present embodiment, the weight reduction portion 88B is formed to have a size that covers the entire electronic component 10C and connection components 20E and 20F when viewed from the Z direction. That is, the width of the weight reduction portion 88B in the Y direction is larger than the width of the electronic component 10C and the connection components 20E and 20F in the Y direction. The length of the weight reduction portion 88B in the X direction is larger than the length of the electronic component 10C and the connection components 20E and 20F in the X direction. However, a size or a shape of the weight reduction portion 88B may be changed as appropriate.

An area of each of the weight reduction portions 88 viewed from the Z direction is larger than an area of each of the heat transfer members 92 viewed from the Z direction. In the present embodiment, a total area of the weight reduction portions 88 (weight reduction portions 88A and 88B) provided to correspond to the first subunit SUX is larger than a total area of the heat transfer members 92 provided to correspond to the first subunit SUX. However, the area of the weight reduction portion 88 may be smaller than the area of the heat transfer member 92.

In the present embodiment, an area occupied by the weight reduction portion 88 in the entire metal plate 80 (flat surface portion 81) may be set according to a heat capacity or the like of the metal plate 80. That is, the heat capacity of the metal plate 80 serving as a heat dissipation plate may be secured by reducing the area of the weight reduction portion 88 as an amount of heat generation of the electronic component 10 or the bus bar 42 increases.

### 8. Heat Transfer

As illustrated in FIG. 11, in the subunit SU, for example, heat is generated when the electronic component 10 is energized or when the bus bar 42 is energized. Part of the heat of the base plate 41 out of the heat generated in the subunit SU is transferred to the metal plate 80 (flat surface portion 81) via the heat transfer member 92 and the insulating sheet 91. Part of the heat of the base plate 41 is transferred to the fixing portion 82 of the metal plate 80 via the fixing portion 52. Further, part of the heat of the electronic component 10 is transmitted to the fixing portion 83 of the metal plate 80 via the attachment portion 14. As described above, the heat generated in the subunit SU is transferred to the metal plate 80 and then released from the metal plate 80 to the outside.

Here, the warm air accumulated in the gap S1 between the metal plate 80 and the base plate 41 is released to the outside of the electrical connection unit 1 through the weight reduction portion 88. This facilitates heat dissipation of the electrical connection unit 1.

In the electrical connection unit 1 of the present embodiment, in the metal plate 80, one or more weight reduction portions 88 penetrating the metal plate 80 in the Z direction are formed at positions overlapping the subunit SU and not overlapping at least part of the heat transfer member 92 when viewed from the Z direction.

According to this constitution, since the weight reduction portion 88 is formed on the metal plate 80, the weight reduction of the metal plate 80 can be achieved compared with a case where the entire metal plate 80 is formed with a uniform thickness. With this constitution, the weight of the electrical connection unit 1 can be reduced. On the other hand, the heat transfer member 92 that thermally connects the subunit SU to the metal plate 80 is provided at a position of the metal plate 80 that does not overlap the weight reduction portion 88 when viewed from the Z direction. Therefore, the heat generated in the subunit SU can be effectively transferred to the metal plate 80. In addition, since the weight reduction portion 88 penetrates the metal plate 80 in the Z direction, it is possible to curb heat from being confined between the metal plate 80 and the subunit SU. With this constitution, the heat dissipation property of the electrical connection unit 1 can also be improved.

In the present embodiment, the heat transfer member 92 is provided at a position overlapping the bus bar 42 when viewed from the Z direction.

According to this constitution, in the subunit SU, the bus bar 42, which is one of heat generation portions, and the metal plate 80 are thermally connected via the heat transfer member 92. With this connection, a heat dissipation property can be further improved.

In the present embodiment, the plurality of weight reduction portions 88 are disposed apart from each other in the horizontal direction.

According to this constitution, the layout property of the weight reduction portion 88 can be improved compared with a case where one large weight reduction portion 88 is formed.

In the present embodiment, the area of the weight reduction portion 88 is larger than the area of the heat transfer member 92 when viewed from the Z direction.

According to this constitution, the area of the weight reduction portion 88 can be secured, and the weight of the electrical connection unit 1 can be further reduced.

In the present embodiment, the electronic component 10 (electronic component 10C) supported by the connection components 20 (connection components 20E and 20F) in a state of being separated from the routing board 40 in the Z direction and electrically connected to the bus bar 42 via the connection component 20 is provided. The weight reduction portion 88 (weight reduction portion 88B) is provided at a position overlapping the electronic component 10 when viewed from the Z direction.

According to this constitution, since the electronic component 10 is provided in a state of being separated from the routing board 40, heat is hardly transferred immediately below from the electronic component 10. By providing the weight reduction portion 88 at a location where heat of the electronic component 10 is hardly transferred immediately below, it is possible to curb deterioration in heat dissipation performance due to weight reduction. In addition, since a load is hardly applied to the periphery of the weight reduction portion 88 via the electronic component 10, it is easy to secure the strength reliability of the metal plate 80.

### 9. Other Modification Examples

Next, several modification examples will be described. Note that a constitution other than that described below in each modification example is the same as the constitution of the above embodiment.

### First Modification Example

The routing board 40 is not limited to a structure in which the base plate 41 and the bus bar 42 are integrated through insert molding. For example, the bus bar 42 may be disposed in the accommodation portion 55 after the base plate 41 provided with the accommodation portion 55 for accommodating the bus bar 42 is molded. In this case, the bus bar 42 may be fixed to the accommodation portion 55 through fitting, or may be fixed to the accommodation portion 55 by using an adhesive or other fixing means. In these cases, potting may be performed to fill a gap between the bus bar 42 and the accommodation portion 55.

### Second Modification Example

A base member of the routing board 40 is not limited to the base plate 41 having the plate-shaped flat surface portion 51. The routing board 40 may be a base member (for example, an insulating sheet) having a sheet-shaped flat surface portion 51. In this case, the accommodation portion 55 may be formed by part of the flat surface portion 51 following the outer shape of the bus bar 42. In the present disclosure, the “sheet-shaped” or “sheet” is not limited to a member having a thickness of 1 mm or more, and a member (so-called a film) having a thickness of less than 1 mm can also be used.

### Third Modification Example

The base plate 41 of the routing board 40 may include a plurality of members (plate members or sheet members). The plurality of members are provided to sandwich the plurality of bus bars 42 arranged in the horizontal direction, for example, from both sides in the Z direction. For example, the plurality of members are integrated by sandwiching the plurality of bus bars 42 through laminate molding, for example. The plurality of members form the flat surface portion 51. In this case, the accommodation portion 55 may be formed in a hollow shape inside the base plate 41 (between the plurality of members). The plurality of members may be a plurality of plate members, a plurality of sheet members, or a combination of a plate member and a sheet member. The sheet member may be, for example, a flexible sheet member. The flat surface portion 51 formed of the plurality of members has an opening through which at least first connection portion 61 and second connection portion 62 of the bus bar 42 are exposed. For example, in this case, the accommodation portion 55 formed between the plurality of members corresponds to an example of an “accommodation portion recessed in the first direction (Z direction)”.

### Fourth Modification Example

A connection between the electronic component 10 and the bus bar 42 is not limited to the connection using the connection component 20. The electronic component 10 may be directly connected to the bus bar 42 by using a fastening member (for example, a bolt or a screw), welding, or the like.

Several embodiments and modification examples have been described above. However, the embodiments and the modification examples are not limited to the examples described above. For example, a plurality of embodiments may be implemented in combination with each other. The present invention is not limited by the above description, but only by the appended claims.

In the above-described embodiment, the electrical connection unit 1 for a vehicle has been described, but the present invention is not limited to this constitution.

In the above embodiment, an example in which the main body MU is constituted by the plurality of subunits SUX, SUY, and SUZ has been described, but the present invention is not limited to this constitution. The electrical connection unit 1 may be constituted by one circuit constitution body.

In the above-described embodiment, the case where the metal plate 80 is adopted as an example of a heat dissipation plate has been described, but the present invention is not limited to this constitution. The heat dissipation plate may be made of a material having a thermal conductivity higher than that of the routing board 40.

In the above embodiment, the constitution in which the metal plate 80 overlaps the entire main body MU has been described, but the present invention is not limited to this constitution. The metal plate 80 may overlap at least part of the main body MU.

In the above embodiment, the constitution in which the plurality of weight reduction portions 88 are provided has been described, but the present invention is not limited to this constitution. The number of the weight reduction portions 88 may be one.

In the above embodiment, the case where the electronic component 10, the bus bar 42, and the connection component 20 are adopted as examples of a resistor has been described, but the present invention is not limited to this constitution. Any resistor can be selected as appropriate as long as the resistor is a heat generation component that generates heat when energized.

In the above embodiment, the constitution in which each weight reduction portion 88 is one large opening (through-hole) has been described, but the present invention is not limited to this constitution. The weight reduction portion 88 may constitute one weight reduction portion 88 by gathering a plurality of small openings formed in a lattice shape, a honeycomb shape, or a slit shape. In this case, since the surface area of the metal plate 80 can be secured by a portion of the metal plate 80 that partitions the small openings, the heat dissipation property can be improved.

In the above-described embodiment, the constitution in which the routing board 40 and the bus bar 42 are integrally formed has been described, but the present invention is not limited to this constitution. The bus bar 42 may be formed separately from the routing board 40.

In the above embodiment, the constitution in which the entire weight reduction portion 88 is disposed at the position shifted with respect to the heat transfer member 92 has been described, but the present invention is not limited to this constitution. Part of the weight reduction portion 88 and the heat transfer member 92 may overlap each other when viewed from the Z direction.

In the above embodiment, the constitution in which the weight reduction portion 88 is formed of a through-hole has been described, but the present invention is not limited to this constitution. The weight reduction portion 88 may be a thin portion formed to be thinner than other portions in the flat surface portion 81. The thin portion may be open on the +Z direction side or the −Z direction side of the flat surface portion 81. Both a through-hole and a thin portion may be formed in a mixed manner in one metal plate 80.

Although the embodiments of the present disclosure have been described and illustrated above, the embodiments are illustrated as examples and are not intended to limit the scope of the present disclosure. The above-described embodiments can be implemented in various other forms, and the constituents in the above-described embodiments can be replaced with well-known constituents, and various additions, omissions, substitutions, and changes can be made without departing from the concept of the present disclosure.

### INDUSTRIAL APPLICABILITY

According to the present disclosure, it is possible to provide an electrical connection unit that can be reduced in weight.

### REFERENCE SIGNS LIST

1 Electrical connection unit
10, 10A, 10B, 10C, 10M, 10N, 10X, 10Y, 10Z Electronic component (resistor, first resistor)
20, 20A, 20B, 20C, 20D, 20E, 20F, 20M, 20N, 30A, 30B Connection component (resistor, first resistor)
40, 40X First routing board (board)
40, 40Y Second routing board (board)
40, 40Z Third routing board (board)
42, 42A, 42B, 42C, 42D, 42E Bus bar (resistor, first resistor)
80 Metal plate (heat dissipation plate)
88, 88A, 88B Weight reduction portion
92 Heat transfer member
100 Connection component (resistor)
SU, SUX, SUY, SUZ Subunit (circuit constitution body)

What is claimed is:

1. An electrical connection unit comprising:
a circuit constitution body having a plurality of resistors and a board facing the plurality of resistors;
a heat dissipation plate provided to overlap the circuit constitution body in a thickness direction of the board, the heat dissipation plate being made of a material having a thermal conductivity higher than a thermal conductivity of the board; and
one or more heat transfer members provided between the circuit constitution body and the heat dissipation plate and thermally connecting the circuit constitution body to the heat dissipation plate,
wherein one or more weight reduction portions that are formed to be thinner than other portions of the heat dissipation plate or penetrate the heat dissipation plate in the thickness direction are formed in the heat dissipation plate at positions overlapping the board and not overlapping at least a part of the heat transfer member when viewed from the thickness direction.

2. The electrical connection unit according to claim 1, wherein
the plurality of resistors include a first resistor, and
the heat transfer member is disposed at a position overlapping at least a part of the first resistor when viewed from the thickness direction.

3. The electrical connection unit according to claim 1, wherein
the one or more weight reduction portions include a plurality of weight reduction portions disposed apart from each other.

4. The electrical connection unit according to claim 1, wherein
an area of the one or more weight reduction portions is larger than an area of the one or more heat transfer members when viewed from the thickness direction.

5. The electrical connection unit according to claim 1, wherein
the plurality of resistors include a first resistor,
wherein the first resistor includes
a bus bar held by the board,
a connection component electrically connected to the bus bar in a state of standing from the board in the thickness direction, and
an electronic component supported by the connection component in a state of being separated from the board in the thickness direction and electrically connected to the bus bar via the connection component, and
wherein the weight reduction portion is provided at a position overlapping the electronic component when viewed from the thickness direction.
